(19) United States
(12) Patent Application Publication
(10) Pub. No.: US 2008/0044593 A1
(43) Pub. Date: Feb. 21, 2008

(54) METHOD OF FORMING A MATERIAL LAYER

(75) Inventors: Jung-Hun Seo, Gyeonggi-do (KR); Eun-Taeck Lee, Gyeonggi-do (KR); Soo-Hwan Kim, Gyeongsangnam-do (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/782,087

(22) Filed: Jul. 24, 2007

(30) Foreign Application Priority Data
Aug. 17, 2006 (KR) 10-2006-0077748

(51) Int. Cl. H05H 1/24; C23C 16/00

(52) U.S. Cl. 427/569; 427/255.23

(57) ABSTRACT

A method of processing a wafer in a chamber including a wafer stage and a showerhead is disclosed. The method includes forming a first protection layer on the wafer stage, heating the wafer stage to a first temperature, heating the showerhead at a second temperature lower than the first temperature, forming a second protection layer on inner surfaces of the process chamber including at least the wafer stage and showerhead, loading a wafer onto the wafer stage, forming a material layer on the wafer, and then unloading the wafer from the wafer stage, and removing by-products generated on the inner surfaces of the process chamber during formation of the material layer while maintaining the first temperature of the wafer stage and the second temperature of the showerhead.

### CROSS-REFERENCE TO RELATED APPLICATION

This application claims priority under 35 USC §119 to Korean Patent Application No. 2006-77748 filed Aug. 17, 2006, the subject matter of which is hereby incorporated by reference.

### BACKGROUND OF THE INVENTION

1. Field of the Invention

The present invention relates to a method of forming a material layer on a wafer disposed in a process chamber.

2. Description of the Related Art

The manufacture of contemporary semiconductor devices involves the application of numerous fabrication processes. Some of these fabrication processes form desired material layers on a subject wafer. The material layers are subsequently patterned and connected to form functional circuits including constituent circuit elements. Amongst the many different material layers formed on wafers are various metal layers. The undesired diffusion of a metal layer into surrounding material layers has become a significant problem as the design rules for semiconductor devices has been reduced. To prevent the diffusion of a metal layer, a metal/metal nitride layer such as a titanium/titanium nitride layer has been conventionally used as a barrier layer.

Generally, a titanium/titanium nitride layer may be formed by a deposition process performed at a high temperature of about 400° C. to about 700° C. in a specialized process chamber. Conventional process chambers adapted to the performance of barrier layer deposition processes at the high temperature typically include a wafer stage formed from aluminum and adapted to seat the target wafer, and a showerhead formed from nickel or aluminum and adapted to distribute gas(es) involved in the deposition process.

After performing the deposition process, a cleaning gas including fluorine (F2), nitrogen trifluoride (NF3), etc., may be introduced to the process chamber to remove any titanium layer or titanium nitride layer accumulated on the exposed inner surfaces of the process chamber. Removal of these residual layers is necessary to prevent contamination of subsequently processed wafers.

When the cleaning process is performed at a temperature substantially the same as the process temperature, the aluminum forming the wafer stage may chemically react with a cleaning gas to form aluminum fluoride (AlF3). A powder film resulting from the aluminum fluoride (AlF3) gas may form on the surface of the wafer stage and/or portions of the showerhead. Additionally, the nickel or aluminum forming the showerhead may react with the cleaning gas to form powder-like nickel fluoride (NiF2) or aluminum fluoride (AlF3). This accumulation of nickel fluoride (NiF2) and/or aluminum fluoride (AlF3) may adversely affect process reproducibility and/or generate contamination particles during subsequently performed processes. Furthermore, the aluminum fluoride (AlF3) and/or the nickel fluoride (NiF2) formed by the foregoing may inhibit the effective remove of titanium and/or the titanium nitride layers from the inner surfaces of the process chamber.

### SUMMARY OF THE INVENTION

Example embodiments of the present invention provide a method that is capable of forming a material layer on a wafer without generating a powdery contamination layer on exposed inner surfaces of a process chamber.

In one embodiment, the invention provides a method of processing a wafer in a chamber including a wafer stage and a showerhead, the method comprising; forming a first protection layer on the wafer stage, heating the wafer stage to a first temperature, heating the showerhead at a second temperature lower than the first temperature, forming a second protection layer on inner surfaces of the process chamber including at least the wafer stage and showerhead, loading a wafer onto the wafer stage, forming a material layer on the wafer, and then unloading the wafer from the wafer stage, and removing by-products generated on the inner surfaces of the process chamber during formation of the material layer while maintaining the first temperature of the wafer stage and the second temperature of the showerhead.

### BRIEF DESCRIPTION OF THE DRAWINGS

FIG. (FIG.) 1 is a cross-sectional view illustrating an apparatus for forming a material layer in accordance with an embodiment of the invention;

FIG. 2 is a flow chart illustrating a method of forming a layer using the apparatus in FIG. 1;

FIGS. 3 to 10 are cross-sectional views illustrating a wafer stage and a showerhead of the apparatus in FIG. 1;

FIG. 11 is a flow chart illustrating a method of forming a layer in accordance with another embodiment of the invention; and

FIGS. 12 to 17 are cross-sectional views illustrating a wafer stage and a showerhead of an apparatus for performing the method in FIG. 11.

### DESCRIPTION OF THE EMBODIMENTS

Embodiments of the invention will now be described with reference to the accompanying drawings. This invention may, however, be embodied in many different forms and should not be construed as being limited to only the embodiments set forth herein. In the drawings, the size and relative sizes of layers and regions may be exaggerated for clarity. Throughout the drawings and written description, like reference numbers refer to like or similar elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating an apparatus for forming a material layer in accordance with an embodiment of the invention.

Referring to FIG. 1, the apparatus 100 for forming a material layer includes a chamber 100 having a cylindrical or box shape. A wafer stage 120 is disposed horizontally in the chamber 100 and is adapted to support a wafer W. It is assumed throughout this description that a process adapted to the formation of a metal/metal nitride layer, such as a titanium/titanium nitride layer, is performed. Since this process is performed at relatively high temperature, the wafer stage 120 will be formed from aluminum or some other metal having a high thermal conductivity. For example, the wafer stage 120 may be formed from aluminum (Al), aluminum nitride (AlN), etc.

A wafer stage heater 130 may be built into the wafer stage 120. Power is supplied to the wafer stage heater 130 from a power source (not shown), such that a wafer W mounted on the wafer stage 120 is heated to a predetermined temperature.

It is assumed that a titanium layer or a titanium nitride layer is formed on the wafer W. Following formation of this material layer on the wafer W, while removing the titanium nitride layer from chamber 110, the wafer stage heater 130 maintains the wafer stage 120 at a constant cleaning temperature. In one embodiment, the cleaning temperature ranges from about 400° C. to about 700° C.

Additionally, a cooling line 140 for cooling the wafer stage 120 or the wafer W mounted on the wafer stage 120 may be arranged in relation to the wafer stage 120. The cooling line 140 circulates a refrigerant to cool the wafer W or the wafer stage 120 in order to reduce the temperature of one or both of these elements.

A showerhead 150 is installed above and facing the wafer stage 120 in an upper portion of the chamber 110. The showerhead 150 may have a circular planar shape and may be formed from nickel or aluminum. In the illustrated example, the showerhead 150 may include an upper plate 151, a middle plate 152 and a lower plate 153.

A first gas introduction pipe 156 and a second gas introduction pipe 157 are connected to the showerhead 150. In the illustrated example, the showerhead 150 has a matrix type structure that separately supplies gas(es) to the chamber 110 as provided by the first introduction pipe 156 and the second introduction pipe 157, respectively. That is, the gas supplied from the first introduction pipe 156 and the gas supplied from the second introduction pipe 157 need not be mixed by showerhead 150, but may be separately introduced into the chamber 110.

In the illustrated example, a reaction gas provision unit 160 may include a nitrogen trifluoride (NF3) gas source 161 (nitrogen trifluoride (NF3) gas being used as one possible cleaning gas), a titanium tetrachloride (TiCl4) gas source 162 (titanium tetrachloride (TiCl4) being used as one possible process or reaction gas), an argon (Ar) gas source 163 (argon (Ar) gas being one possible carrier gas), a hydrogen (H2) gas source 164 (hydrogen (H2) gas being one possible reduction gas), and an ammonia (NH3) gas source 165 (ammonia (NH3) gas being another process or reaction gas). These exemplary possibilities may be used to form a material layer of titanium nitride of the wafer W.

In this example embodiment, nitrogen trifluoride (NF3) may be assumed as a cleaning gas. Alternatively, another gas including fluorine may be used as the cleaning gas. For example, the cleaning gas may include a nitrogen trifluoride (NF3) gas, a fluorine (F2) gas, a hexafluoroethane (C2F6) gas, and so on. These may be used alone or in combination. Additionally or alternatively, a gas including chloride may be used as a cleaning gas. For example, chlorine trifluoride (ClF3), chlorine (Cl2), etc., might be used.

The nitrogen trifluoride (NF3) gas source 161, the titanium tetrachloride (TiCl4) gas source 162 and the argon (Ar) gas source 163 may be connected to the first introduction pipe 156. Further, the hydrogen (H2) gas source 164 and the ammonia (NH3) gas source 165 may be connected to the second introduction pipe 157. During formation of a titanium layer on the wafer W, titanium tetrachloride (TiCl4) gas and hydrogen (H2) gas are separately introduced, but not mixed during introduction, to the chamber 110 and then mixed within the chamber 110. During formation of a titanium nitride layer, titanium tetrachloride (TiCl4) gas and ammonia (NH3) gas are separately introduced, but not mixed during introduction, to the chamber 110 and then mixed within the chamber 110.

In this embodiment, argon gas is used as a carrier gas. Alternatively, nitrogen (N2) gas or helium (He) gas may be used as a carrier gas. Also, although not shown in the figures, a flow controller and an opening/shutting valve may be respectively provided between the various gas source(s) and the gas introduction pipe(s) to vary the nature and quantity of gases provided via the gas introduction pipe(s).

In the illustrated example, a showerhead heater 170 may be mounted on an upper surface of the upper plate 151. The showerhead heater 170 is connected to a power source 172 which heats the showerhead 150 to a constant temperature.

In the context of the working example, during removal of the titanium nitride layer from inner surfaces of the chamber 110, the showerhead heater 170 maintains the showerhead 150 at a constant temperature in a range of from about 150° C. to about 300° C.

A power supply rod 184 is connected to the upper surface of the upper plate 151 of the showerhead 150. The power supply rod 184 is connected to a high frequency power source 180 through a conformer 182. Thus, high frequency electrical power may be supplied to the showerhead 150 from the high frequency power source 180.

The high frequency power source 180 may be turned ON/OFF at will to apply the high frequency power. When a titanium layer is formed on the wafer W, the high frequency power source 180 is turned ON to generate plasma from the titanium tetrachloride (TiCl4) gas and hydrogen (H2) gas introduced into the chamber 110. When cleaning the inner surfaces of the chamber 110, the high frequency power source 180 is also turned ON to generate plasma from the ammonia (NH3) gas introduced into chamber 110.

In the illustrated embodiment, gases within the chamber 110 may be placed in a plasma state by application of energy from the high frequency power source 180, as connected to the showerhead 150. Alternatively, the gases may be placed into a plasma state outside the chamber 110 and then be introduced into chamber 110.

When forming a titanium nitride layer on the wafer W, titanium tetrachloride (TiCl4) gas and hydrogen (H2) gas introduced into the chamber 110 are thermally decomposed by the high temperature, so the high frequency power source 180 may be turned OFF.

In the illustrated example, an exhaust pipe 114 is connected to a lower portion of the chamber 110 and an exhaust unit 116. The exhaust unit 116 operates to exhaust non-reactant gases and by-products from the chamber 110. The chamber 110 may be placed in a vacuum state of predetermined pressure by operation of the exhaust unit 116.

A drive unit 190 is connected to the wafer stage 120 to move the wafer stage 120 vertically (upward and downward). Thus, the distance between the wafer stage 120 and the showerhead 150 may be precisely controlled. For example, when a titanium layer is formed on the wafer W, the distance between the wafer stage 120 and the showerhead 150 will be relatively small. In contrast, when a titanium nitride layer is formed on the wafer W, the distance between the wafer stage 120 and the showerhead 150 will be relatively large.

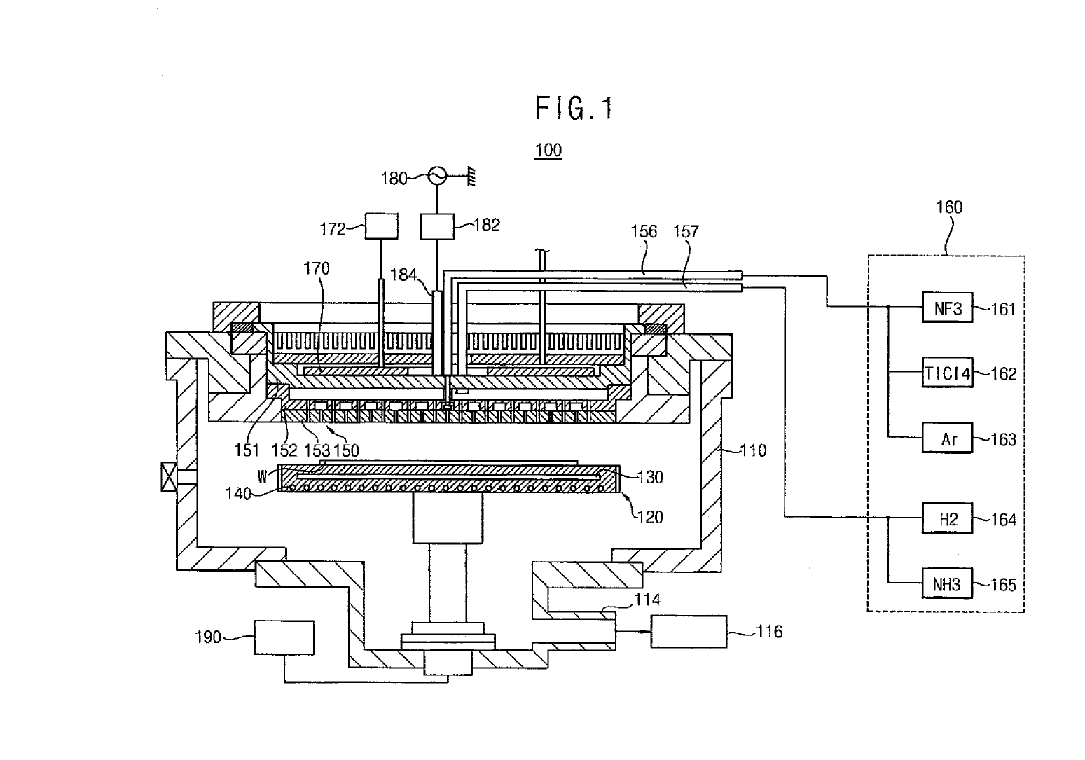

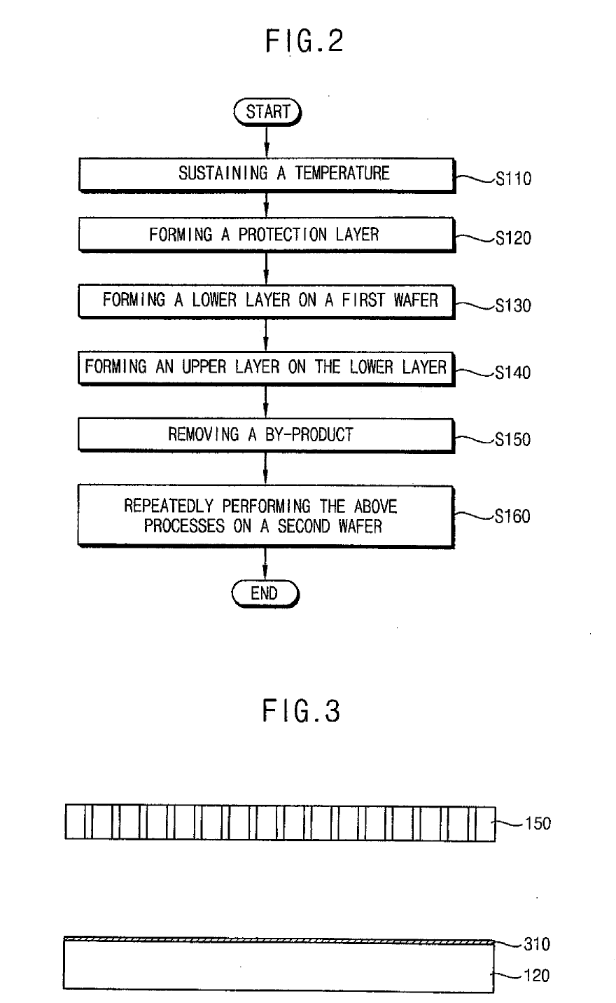

FIG. 2 is a flow chart illustrating a method of forming a material layer using the apparatus in FIG. 1. FIGS. 3 to 10 are related cross-sectional views further illustrating the relationship of wafer stage 120 and showerhead 150 of the apparatus in FIG. 1. It should be noted that the first by-products and second by-products described hereafter are formed on exposed inner surface of the chamber 110, although such elements are illustrated in FIGS. 3 to 9 only in relation to the wafer stage 120 and the showerhead 150.

Referring to FIGS. 2 and 3, a first protection layer such as an aluminum fluoride (AlF3) layer 310 is formed on the upper surface of the wafer stage 120. The aluminum fluoride (AlF3) layer 310 will protect the aluminum material that forms the wafer stage 120. Here, since the aluminum fluoride (AlF3) layer 310 is chemically stable it will not be reacted with an applied cleaning gas during a dry cleaning process adapted to clean the chamber 110. Further, the aluminum fluoride (AlF3) layer 310 prevents fluorine from a cleaning gas from making contact with the aluminum material forming the wafer stage 120. Accordingly, the wafer stage 120 will not be etched by the cleaning gas and the resulting powdery aluminum fluoride (AlF3) will not be generated on the surface of the wafer stage 120.

In the method illustrated in FIG. 2, the showerhead heater 170 heats the showerhead 150 to a constant temperature in a range of from about 150° C. to 300° C. (S110). In one more specific embodiment, showerhead heater 170 heats showerhead 150 to a uniform temperature in a range of from about 180° C. to 250° C. Because the showerhead 150 is maintained at a relatively low temperature less than about 300° C., the nickel or aluminum material forming the showerhead 150 will not be reacted with fluorine in the cleaning gas. Thus, the powdery nickel fluoride (NiF2) or aluminum fluoride (AlF3) is not generated. During this process, the wafer stage heater 130 heats the wafer stage 120 to a constant temperature in a range of from about 400° C. to about 700° C.

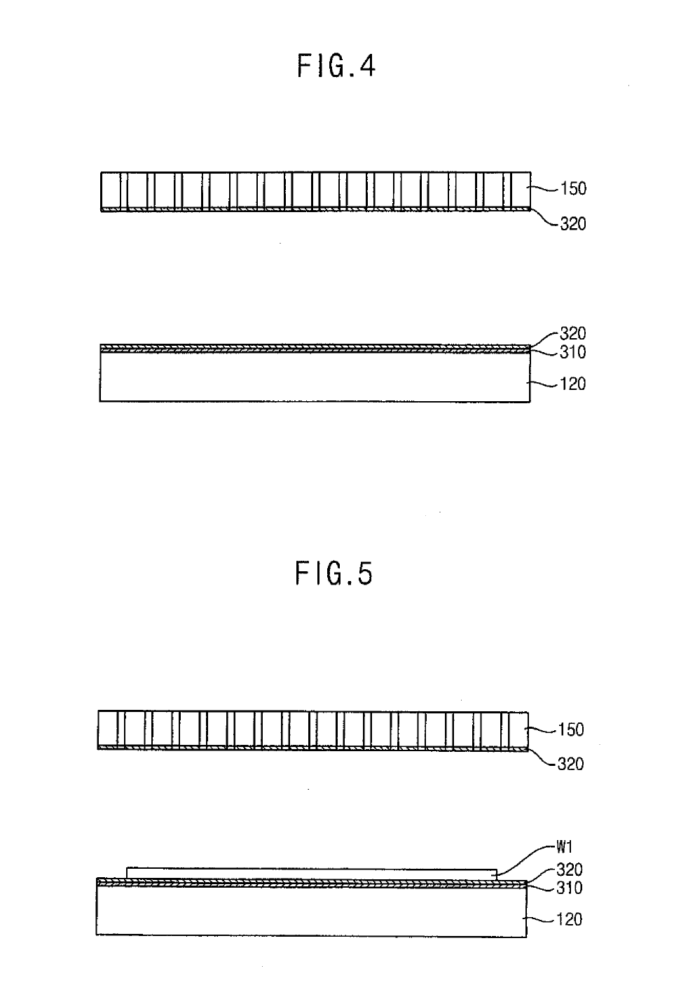

Referring to FIGS. 2 and 4, a reaction gas such as hydrogen (H2) gas, and/or titanium tetrachloride (TiCl4) gas along with argon (Ar) gas may be introduced into the chamber 110 to form a first titanium layer 320 (S120). The first titanium layer 320 may be formed, for example, by a plasma-enhanced chemical vapor deposition (PECVD) process. A high frequency electrical power is supplied to the showerhead 150 from the high frequency power source 180 to generate plasma from the reaction gas. Accordingly, a second protection layer such as a first titanium layer 320 may be formed on the inner surfaces of the chamber 110, (e.g., the inner walls of the chamber 110, the surface of the wafer stage 120, and the surface of the showerhead 150).

When the first titanium layer 320 is formed with a uniform thickness, it will reflect heat back towards the center of chamber 110. Further, the first titanium layer 320 may be used to remove residual fluorine following cleaning of the chamber 110. As fluorine is removed, the specific resistance characteristics of the titanium layer and the titanium nitride layer formed on the wafer are improved.

During formation of the first titanium layer 320, the application of electric power by the high frequency power source 180, and the introduction of hydrogen (H2) gas, titanium tetrachloride (TiCl4) gas and argon (Ar) gas are suspended. A cleaning gas such as nitrogen trifluoride (NF3) gas may be introduced to the chamber 110 by the reaction gas provision unit 160. The exhaust unit 116 then operates to exhaust non-reactant gas and by-products generated during formation of the titanium layer.

Referring to FIGS. 2 and 5, a first wafer W1 is loaded onto the wafer stage 120 through a gate valve (not illustrated) installed in the chamber 110.

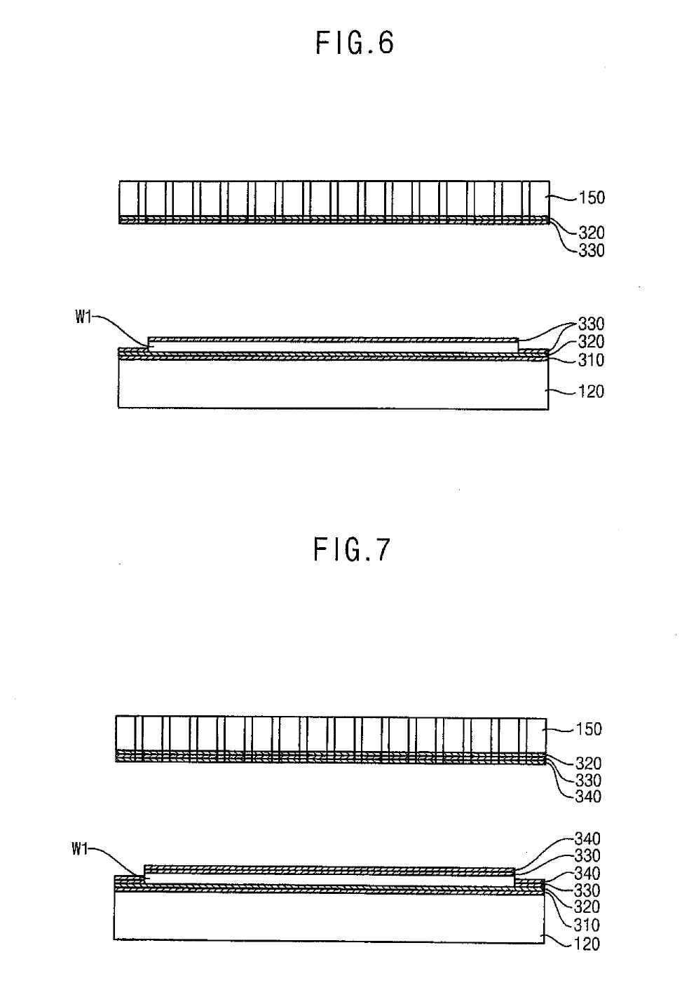

Referring to FIGS. 2 and 6, in order to form a second titanium layer 330, the drive unit 190 is operated to adjust the separation distance (i.e., define a first separation gap) between the wafer stage 120 and the showerhead 150. The wafer stage heater 130 maintains the wafer stage 120 at a defined temperature during formation of the first titanium layer 320. Further, the showerhead heater 170 maintains the showerhead 150 at a defined temperature during formation of the first titanium layer 320.

A reaction gas, including (e.g.,) hydrogen (H2) gas, titanium tetrachloride (TiCl4) gas, etc., along with one or more carrier gas(es) like argon (Ar) gas are then introduced into the chamber 110 to form a second titanium layer 330 (S130). The second titanium layer 330 may be formed by a plasma-enhanced chemical vapor deposition (PECVD) process. High frequency electrical power may be supplied to the showerhead 150 from the high frequency power source 180 to generate plasma from the reaction gas(es). Accordingly, the second titanium layer 330 is formed on the first wafer W1 with a first adhesive force.

Here, first by-products including the second titanium layer 330 may also be formed on inner surfaces of the chamber 110 with the first adhesive force.

Following formation of the second titanium layer 330, the application of electrical power by the high frequency power source 180, and the introduction of hydrogen (H2) gas, titanium tetrachloride (TiCl4) gas and argon (Ar) gas is suspended. A cleaning gas such as the nitrogen trifluoride (NF3) gas is then supplied to the chamber 110 by the gas provision unit 160. The exhaust device 116 may be used to exhaust non-reactant gases and by-products generated during formation of the second titanium layer 330.

Referring to FIGS. 2 and 7, after cleaning the inside of the chamber 110, in order to form a titanium nitride layer 340, the drive unit 190 again operates to establish a second separation gap between the wafer stage 120 and the showerhead 150, where the second separation gap is wider than the first separation distance. Wafer the stage heater 130 then maintains the wafer stage 120 at substantially the same temperature at which the second titanium layer 330 was formed. Further, the showerhead heater 170 maintains the showerhead 150 at substantially the same temperature at which the second titanium layer 330 was formed.

A reaction gas, including ammonia (NH3) gas, titanium tetrachloride (TiCl4) gas along with one or more carrier gas(es) like argon (Ar) gas are introduced into the chamber 110 to form the titanium nitride layer 340 (S140). Because the titanium nitride layer 340 may be formed by a thermal chemical vapor deposition (CVD) process, the high frequency electrical power source 180 may be turned OFF. Accordingly, the second titanium layer 340 is formed with a second adhesive force weaker than the first adhesive force on the second titanium layer 330.

Here, second by-products including the titanium nitride layer 340 adhere to the first by-product formed on inner surfaces of the chamber 110 with a second adhesive force. Of note, however, the second by-products including the titanium nitride layer 340 will not adhere to the showerhead 150 because the showerhead 150 is maintained at a temperature below about 300° C.

Following formation of the titanium nitride layer 340, the introduction of ammonia (NH3) gas, titanium tetrachloride (TiCl4) gas and argon (Ar) gas is suspended. Nitrogen trifluoride (NF3) gas may be used as a cleaning gas and is subsequently introduced into the chamber 110 by the gas provision unit 160. The exhaust devices 116 may then again be operated to exhaust non-reactant gases and by-products generated during the formation of the titanium nitride layer 330.

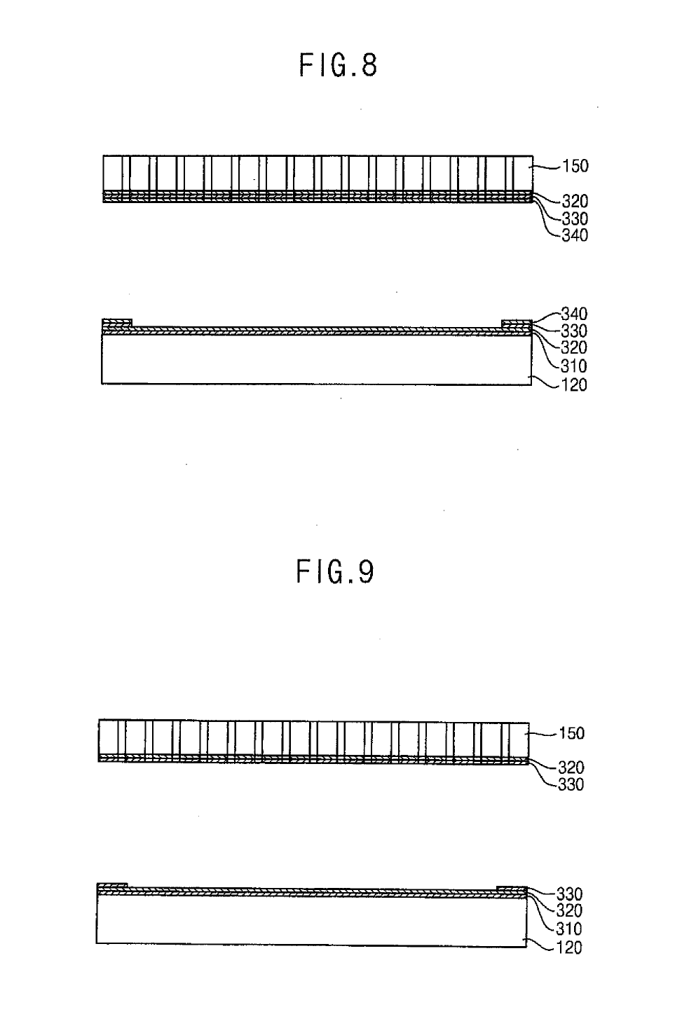

Referring to FIGS. 2 and 8, after the titanium/titanium nitride layer is formed, the gate valve may be opened to unload the first wafer W1 from the chamber 110.

However, when the process of forming the titanium/titanium nitride layer on a second wafer W2 is contemplated, the second by-products formed during the foregoing may be lifted off the inner surfaces of the chamber 110 due to their relatively weak adhesive force. When lifted, the second by-products become contamination particles circulating in the chamber 110 and corrupting the material layers apparent on second wafer W2. Therefore, it is necessary to remove the second by-products, before proceeding with processing the second (and subsequent) wafers.

Referring to FIGS. 2 and 9, after the first wafer W1 is unloaded from the chamber 110, the gate valve is shut. Here, the respective temperatures of the wafer stage 120 and the showerhead 150 are maintained at substantially the same temperature at which the second titanium layer 330 and the titanium nitride layer 340 were formed.

Further, in order to remove the second by-products, at least one gas including nitrogen trifluoride (NF3) gas, fluorine (F2) gas, chlorine (Cl2) gas, etc., is supplied from the gas provision unit 160

High frequency electrical power is then applied to the showerhead 150 from the high frequency power source 180 to generate plasma from the gases provided into the chamber 110. Alternatively, the plasma may be alternately or additionally generated at a remote plasma generator and then supplied to the chamber 110. Alternately, the high frequency power source 180 may be turned OFF and the cleaning gas(es) may be heated to a high temperature and then provided to the chamber 110. In this manner, the second by-products formed on inner surfaces of the chamber 110 may be removed by reaction with the cleaning gas(es) (S150).

As the second by-products are removed, the aluminum fluoride (AlF3) layer 310 protects the wafer stage 120. Accordingly, fluorine from the cleaning gas will not react with the aluminum material forming the wafer stage 120, and powdery aluminum fluoride (AlF3) is not generated. Additionally, because the temperature of the showerhead 150 may be maintained at no more than about 300° C., the nickel or aluminum material forming the showerhead 150 will not react with fluorine from the cleaning gas, and powdery NiF2 or aluminum fluoride (AlF3) is not generated.

Further, removal of the second by-products may be accomplished without changing the temperatures of the wafer stage 120 and/or the showerhead 150. Accordingly, after the second titanium layer 330 and the titanium nitride layer 340 are formed, the second by-products may be removed immediately because the respective temperatures of the wafer stage 120 and the showerhead 150 remain substantially the same as the temperature used to form the second titanium layer 330 and the titanium nitride layer 340.

When the second by-products are removed, the application of electrical power by the high frequency power source 180 and the introduction of ammonia (NH3) gas are suspended.

Then, a cleaning gas such as nitrogen trifluoride (NF3) gas may be supplied to the chamber 110 by the gas provision unit 160. The exhaust unit 116 may then be used to exhaust non-reactant gases and by-products generated during removal of the second by-products.

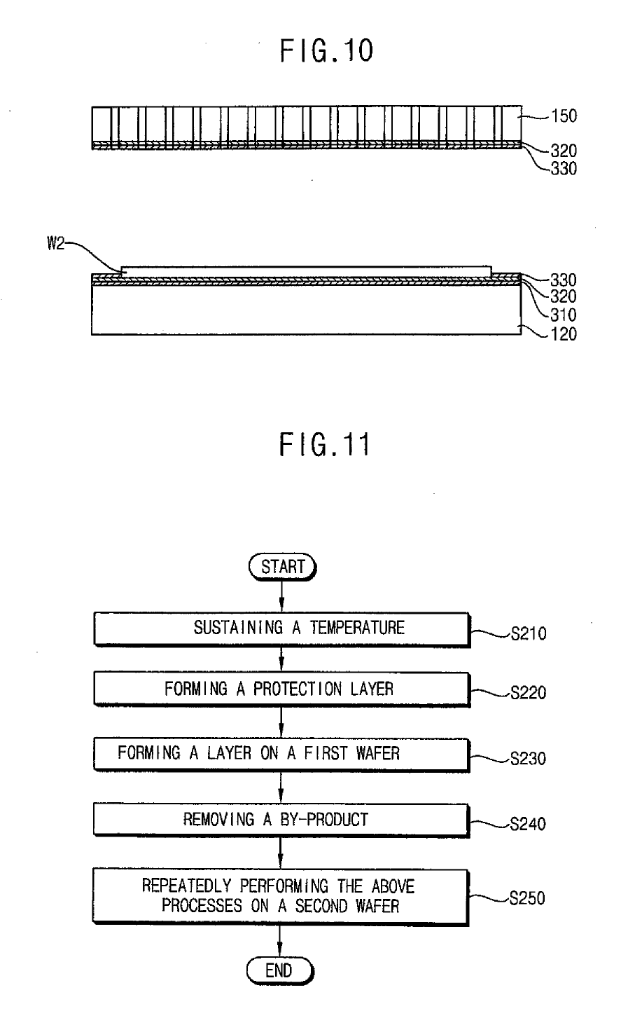

Referring to FIGS. 2 and 10, the above-mentioned method may be performed in relation to a next (or second) wafer W2 (S160). That is, the second wafer W2 may be loaded on the wafer stage 120. Second titanium layer 330 and titanium nitride layer 340 may be formed on the second wafer W2. After unloading the second wafer W2 from the chamber 110, the second by-products formed on inner surfaces of the chamber 110 are removed.

Although the above-mentioned method may be repeated in relation to the second wafer W2, it is not required to change the temperature of the wafer stage 120 or the showerhead 150. Accordingly, after the removal of the second by-products, the method may be immediately performed on the second wafer W2 without any delay arising from a need to re-adjust the temperature of these elements.

According to another example embodiment of the present invention, after a second protection layer, such as first titanium layer 320, is formed on the inner surfaces of the chamber 110, the method may be performed in relation to the second wafer W2 because the first titanium layer 320 may be removed while removing the second by-products, or fluorine from the cleaning gas that is used during removing the second by-product may remain again.

In this embodiment, the first titanium layer 320 may be formed on the inner surfaces of the chamber 110, and the second titanium layer 330 and the titanium nitride layer 340 may be sequentially formed on the wafers W1 and W2. Alternatively, a metal layer such as a tungsten layer and tantalum layer may be formed on the inner surfaces of the chamber 110, and a metal layer such as a tungsten layer and tantalum layer and a metal nitride layer such as a tungsten nitride layer and tantalum nitride layer may be formed on the wafers W1 and W2.

The foregoing method of forming material layer(s) may be carried out by an in-situ process within the chamber 110. Additionally, the second by-products formed in the chamber 110 may be removed to prevent the generation of contamination particles. As the first protection layer may be formed on the wafer stage and the temperature of the showerhead may be maintained at a relatively low level, the powdery residue conventionally associated with use of an applied cleaning gas is not generated.

In addition, as the temperature of the wafer stage 120 and the showerhead 150 are allowed to remain constant, the delay conventionally associated with returning the wafer stage 120 and the showerhead 150 to desired process temperatures is greatly reduced or eliminated, thereby improving the efficiency of layer formation.

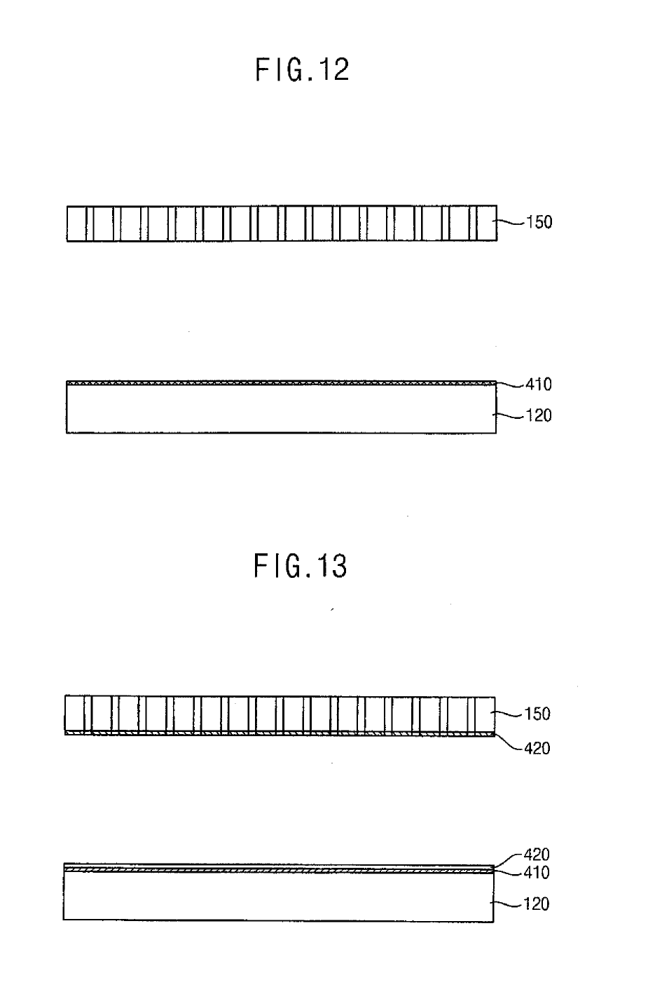

FIG. 11 is a flow chart illustrating a method of forming a material layer in accordance with another embodiment of the invention. FIGS. 12 to 17 are related cross-sectional views further illustrating the relationship between wafer stage 120 and showerhead 150 within the apparatus used to perform the method of FIG. 11.

Referring to FIGS. 11 and 12, the wafer stage 120 on which a first protection layer such as the aluminum fluoride (AlF3) layer 410 is formed is maintained at a first temperature ranging from about 400° C. to about 700° C., and the showerhead 150 is maintained at a second temperature ranging from about 150° C. to about 300° C. (S210).

Since the aluminum fluoride (AlF3) layer 410 is chemically stable, it does not react with a cleaning gas during a dry cleaning process applied to the chamber 110. Further, the aluminum fluoride (AlF3) layer 410 prevents fluorine from the cleaning gas from making contact with the aluminum material forming the wafer stage 120. Accordingly, the wafer stage 120 does not etched under the effects of the applied cleaning gas and powdery aluminum fluoride (AlF3) is not generated on the surface of the wafer stage 120. During this process, wafer stage heater 130 heats the wafer stage 120 and the showerhead heater 170 heats the showerhead 150, as above.

Referring to FIGS. 11 and 13, a second protection layer, such as a first titanium layer 420, is formed on the inner surfaces of the chamber 110 (S220).

Here, as before, a reaction gas, including (e.g.,) hydrogen (H2) gas, titanium tetrachloride (TiCl4) gas along with one or more carrier gas(es) like argon (Ar) gas may be introduced into the chamber 110 to form the first titanium layer 420. High frequency electrical power may be supplied to the showerhead 150 from the high frequency power source 180 to generate plasma from the reaction gas. Accordingly, a second protection layer, such as the first titanium layer 420, is formed on the inner surfaces of the chamber 110.

Following formation of the first titanium layer 420, a cleaning gas such as nitrogen trifluoride (NF3) gas is supplied to the chamber 110 by the gas provision unit 160. Then, the exhaust unit 116 operates to exhaust non-reactant gas and by-products generated during formation of the first titanium layer 420.

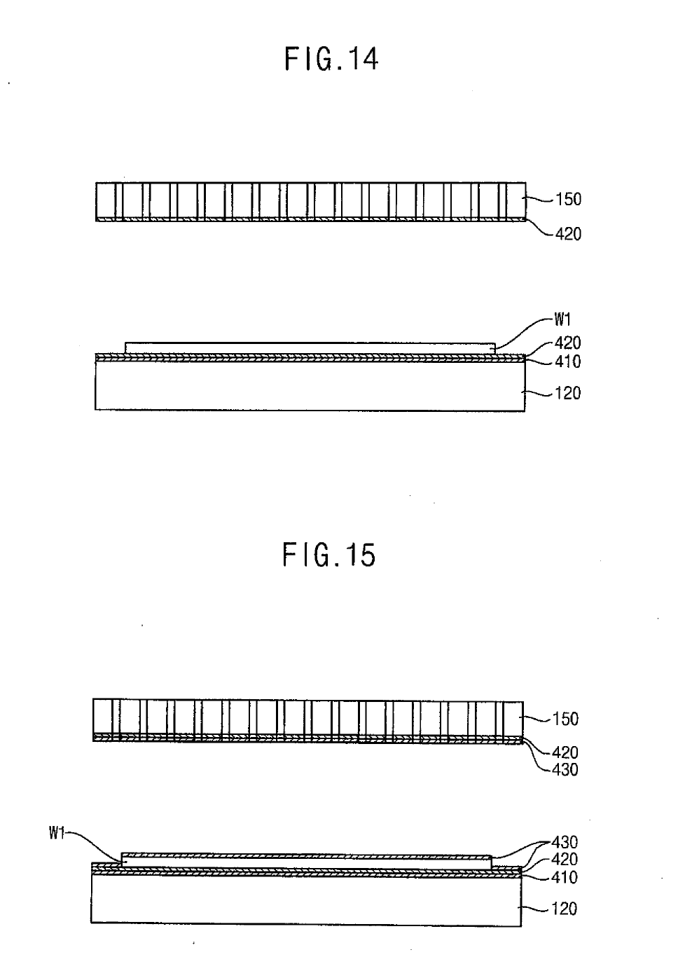

Then, as illustrated in FIG. 14, a first wafer W1 is loaded onto the wafer stage 120 through a gate valve (not illustrated) installed in chamber 110.

Referring to FIGS. 11 and 15, a second titanium layer or a titanium nitride layer 430 may be formed on a first wafer W1 in the chamber 110 (S230).

A reaction gas, including hydrogen (H2) gas, titanium tetrachloride (TiCl4) gas along with one or more carrier gas(es) like argon (Ar) gas may be introduced into the chamber 110 to form the second titanium layer 430.

Alternatively, a reaction gas, including ammonia (NH3) gas, titanium tetrachloride (TiCl4) gas along with one or more carrier gas(es) like argon (Ar) gas, may be introduced into the chamber 110 to form the titanium nitride layer 430. Because the titanium nitride layer 430 may be formed by a thermal chemical vapor deposition (CVD) process, the high frequency electric power source 180 is turned OFF. Accordingly, the titanium nitride layer 430 may be formed on the first wafer W1 in the chamber 110.

Then, the gate valve may be opened to unload the first wafer W1 from the chamber 110.

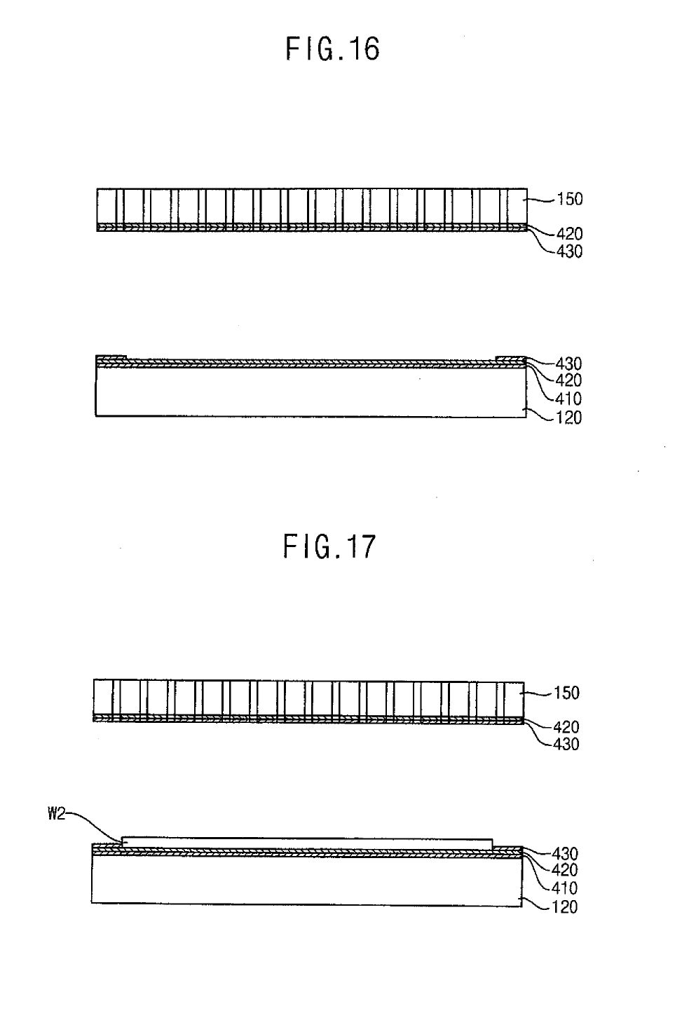

Referring to FIGS. 11 and 16, by-products generated in the chamber 110 during formation of the second titanium layer 430 or the titanium nitride layer 430 are removed (S240). Here, the respective temperatures of the wafer stage 120 and the showerhead 150 may be maintained, as described above.

At least one gas including (e.g.,) nitrogen trifluoride (NF3) gas, fluorine (F2) gas, chlorine (Cl2) gas, etc., is supplied by the gas provision unit 160. Thus, the by-products may be removed by reaction with the cleaning gas(es).

Here, as illustrated in FIG. 16, in a case where the second titanium layer 430 is deposited on the first titanium layer 420 (S230), the second titanium layer 430 may be not removed from the first titanium layer 420 while the by-products are removed. Alternatively, in a case where the titanium nitride layer 430 is deposited on the first titanium layer 420 (S230), the titanium nitride layer 430 may be removed from the first titanium layer 420 together with the by-products.

Referring to FIGS.11 and 17, the second titanium layer 430 or titanium nitride layer 430 may be formed on the second wafer W2 and the by-products may also be removed (S250).

In particular, after the second wafer W2 is loaded onto the wafer stage 120, the second titanium layer 430 or titanium nitride layer 430 may be formed on the second wafer W2 without the need to re-heat the wafer stage 120 or the showerhead 150.

In the subject embodiment of the invention, a detailed description of the process maintaining the wafer stage 120 at the first temperature and the showerhead 150 at the second temperature (S210), the process for forming the first titanium layer 420 (S220), and the process for removing the by-products (S240) may be substantially similar to analogous processes described above in relation to FIGS. 2 to 10.

In addition, a detailed description of the process for forming the second titanium layer 430 or the titanium nitride layer 430 (S230) may be substantially the same as that used to form the second titanium layer 330 (S330) in accordance with the embodiment of the invention illustrated in FIGS. 2 to 10, except that the titanium nitride layer 430 may be formed directly on the first wafer W1.

In this example embodiment, the first titanium layer 420 may be formed on the inner surfaces of the chamber 110, and the second titanium layer 430 or the titanium nitride layer 430 may be formed on the wafers W1 and W2. Alternatively, a metal layer such as a tungsten layer and tantalum layer may be formed, and a metal layer such as a tungsten layer and tantalum layer or a metal nitride layer such as a tungsten nitride layer and tantalum nitride layer may be formed on the wafers W1 and W2.

According to the above-mentioned method of forming the layer, as the first protection layer may be formed on the wafer stage and the temperature of the showerhead may be maintained at a relatively low level, the powdery residue conventionally associated with application of a cleaning gas will not be generated. When the second titanium layer 430 or the titanium nitride layer 430 is formed, the by-products generated in the chamber 110 may be effectively removed thereby preventing the formation of contamination particles.

As residual fluorine from the cleaning process may be removed using the first titanium layer 420, the specific resistance of the titanium layer 430 or the titanium nitride layer 430 may be improved.

In addition, since the temperature of the wafer stage 120 and the showerhead 150 may be maintained constant, the processing time for a sequence of wafers may be improved.

Having described the embodiments of the invention, it is noted that modifications and variations can be made by persons skilled in the art in light of the above teachings. It is therefore to be understood that changes may be made in the particular embodiment of the present invention disclosed which is within the scope of the invention outlined by the appended claims.

What is claimed is:

1. A method of processing a wafer in a chamber including a wafer stage and a showerhead, the method comprising:
forming a first protection layer on the wafer stage;
heating the wafer stage to a first temperature;
heating the showerhead at a second temperature lower than the first temperature;
forming a second protection layer on inner surfaces of the process chamber including at least the wafer stage and showerhead;
loading a wafer onto the wafer stage, forming a material layer on the wafer, and then unloading the wafer from the wafer stage; and
removing by-products generated on the inner surfaces of the process chamber during formation of the material layer while maintaining the first temperature of the wafer stage and the second temperature of the showerhead.

2. The method of claim 1, further comprising:
loading another wafer on the wafer stage following removal of the by-products.

3. The method of claim 1, wherein the first temperature ranges from between 400° C. to about 700° C.

4. The method of claim 1, wherein removing the by-products comprises introducing a cleaning gas into the chamber, and the second temperature is substantially lower than a temperature at which material forming the showerhead reacts with the cleaning gas.

5. The method of claim 4, wherein the second temperature ranges from about 150° C. to about 300° C.

6. The method of claim 4, wherein the cleaning gas comprises at least one selected from a group of gases consisting of nitrogen trifluoride (NF3) gas and fluorine (F2) gas.

7. The method of claim 4, wherein removing the by-products further comprises generating plasma from the cleaning gas.

8. The method of claim 4, wherein removing the by-products further comprises heating the cleaning gas.

9. The method of claim 1, wherein the first protection layer comprises an aluminum fluoride (AlF3) layer.

10. The method of claim 1, wherein the second protection layer comprises a titanium layer.

11. The method of claim 1, wherein the material layer comprises at least one of a titanium layer and a titanium nitride layer.

12. The method of claim 1, wherein forming the material layer on the wafer comprises:
forming a lower material layer on the wafer; and
forming an upper material layer on the lower layer.

13. The method of claim 12, wherein the lower material layer comprises a titanium layer and the upper layer comprises a titanium nitride layer.
